(19) United States
(12) Patent Application Publication
(10) Pub. No.: US 2017/0094842 A1
(43) Pub. Date: Mar. 30, 2017

(54) Power Supply and Method

(71) Applicant: Infineon Technologies Austria AG, Villach (AT)

(72) Inventor: Martin Standing, Velden (AT)

(21) Appl. No.: 14/867,880

(22) Filed: Sep. 28, 2015

(51) Int. Cl. H05K 7/20

(52) U.S. Cl. CPC H05K 7/20927

(57) ABSTRACT

In an embodiment, a power supply includes a casing enclosing a circuit for power conversion including one or more heat generating electronic components mounted on a circuit board, an input port configured to receive electrical energy from a power source, an output port configured to supply electrical energy to an external load, and a dielectric liquid disposed in the casing. The dielectric liquid is thermally coupled with the one or more heat generating electronic components, the circuit board and the casing. The dielectric liquid has a thermal conductivity and a thermal capacitance such that the dielectric liquid provides cooling for the one or more heat generating components and heat distribution by way of the casing such that a temperature of the outer surface of the casing is equalised.

### BACKGROUND

A power supply may be used within or with various electronic apparatus for providing electric power. A power supply may convert an alternating current (AC) source into a direct current (DC) source required by one or more electronic devices. For example, a power supply may be used for converting a mains alternating current into a direct current source suitable for a laptop computer or mobile telephone. Such power supplies, particularly when used external to the electronic device, may also be called adapters, chargers, or power converters.

The electronic components within the power supply may generate thermal energy during operation. In order to avoid the electronic components from becoming undesirably hot, the power supply may include heat dissipation devices. One type of heat dissipation device is a heatsink which may be positioned between the heat generating electronic components and the casing of the power supply so as to transfer the heat to the casing. However, this heat transfer may lead to localised heating of the casing and the formation of so called “hot spots”. It is desirable that the casing, also at any hot spots, does not exceed a desired predetermined temperature. To prevent the casing becoming undesirably hot, an additional fan may be provided to force currents of air to carry the heat from the heatsink to the outside through vents provided in the casing.

Additionally, it is generally desirable to reduce the size of electronic apparatus, including power supplies. However, reducing the size of the power supply reduces the space available for additional heatsinks, fans etc. for heat dissipation. Therefore, a power supply which has a heat dissipation system suitable for avoiding the formation of hot spots and which can have a smaller size is desirable.

### SUMMARY

In an embodiment, a power supply includes a casing enclosing a circuit for power conversion including one or more heat generating electronic components mounted on a circuit board, an input port configured to receive electrical energy from a power source, an output port configured to supply electrical energy to an external load and a dielectric liquid disposed in the casing. The dielectric liquid is thermally coupled with the one or more heat generating electronic components, the circuit board and the casing. The liquid has a thermal conductivity and a thermal capacitance such that the dielectric liquid provides cooling for the one or more heat generating components and heat distribution by way of the casing such that a temperature of the outer surface of the casing is equalised.

In an embodiment, a method includes receiving, at an input port of a power supply, electrical energy from a power source, supplying the received electrical energy to one or more of a rectifier and a switching transistor and dissipating at least a portion of thermal energy generated by one or more of the rectifier and the switching transistor from the power supply by way of convection of a dielectric liquid that is thermally coupled with the one or more of the rectifier and the switching transistor and a casing of the power supply such that a temperature at an outer surface of the casing is equalised.

In an embodiment, a power supply includes means for enclosing a dielectric liquid in a liquid-tight manner, means for receiving, at an input port of a power supply, electrical energy from a power source, means for converting the received electrical energy by one or more of a rectifier and a switching transistor, means for transmitting the converted electrical energy to an external load and means for dissipating at least a portion of thermal energy generated by one or more of the rectifier and the switching transistor by way of the liquid and the means for enclosing the dielectric liquid such that a temperature at an outer surface of the means for enclosing the liquid is equalised.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Exemplary embodiments are depicted in the drawings and are detailed in the description which follows.

FIG. 1a illustrates an exemplary circuit diagram of a power supply.

FIG. 1b illustrates an exemplary circuit diagram of a power supply.

FIG. 2 illustrates a three-dimensional perspective view of a power supply.

FIG. 3 illustrates a three-dimensional perspective view of a power supply.

FIG. 4 illustrates a top view of a power supply.

FIG. 5 illustrates a side view of a power supply.

FIG. 6 illustrates a cross-sectional view of the power supply of FIG. 5 along the line A-A.

FIG. 7 illustrates a top view of the power supply of FIG. 5.

FIG. 8 illustrates a cross-sectional view of the power supply of FIG. 7 along the line B-B.

FIG. 9 illustrates a cross-sectional view of a power supply.

FIG. 10a illustrates a cross-sectional view of a power supply in a first operation state.

FIG. 10b illustrates a cross-sectional view of a power supply in a second operation state.

FIG. 11 illustrates a perspective view of a casing and power supply.

FIG. 12 illustrates a cross-sectional view of a power supply.

### DETAILED DESCRIPTION

In the following detailed description, reference is made to the accompanying drawings, which form a part hereof, and in which is shown by way of illustration specific embodiments in which the invention may be practiced. In this regard, directional terminology, such as “top”, “bottom”, “front”, “back”, “leading”, “trailing”, etc., is used with reference to the orientation of the figure(s) being described. Because components of the embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, thereof, is not to be taken in a limiting sense, and the scope of the present invention is defined by the appended claims.

A number of embodiments will be explained below. In this case, identical structural features are identified by identical or similar reference symbols in the figures. In the context of the present description, “lateral” or “lateral direction” should be understood to mean a direction or extent that runs generally parallel to the lateral extent of a semiconductor material or semiconductor carrier. The lateral direction thus extends generally parallel to these surfaces or sides. In contrast thereto, the term “vertical” or “vertical direction” is understood to mean a direction that runs generally perpendicular to these surfaces or sides and thus to the lateral direction. The vertical direction therefore runs in the thickness direction of the semiconductor material or semiconductor carrier.

As employed in this specification, the terms “coupled” and/or “electrically coupled” and “thermally coupled” are not meant to mean that the elements must be directly coupled together-intervening elements may be provided between the “coupled” or “electrically coupled” or “thermally coupled” elements.

Embodiments described herein provide a power supply with a liquid cooling system. “Liquid” is used herein to describe the physical state of a material or compound.

The power supply may include a casing enclosing a circuit for power conversion which includes one or more heat generating electronic components mounted on a circuit board. The power supply further includes an input port configured to receive electrical energy from a power source, an output port configured to supply electrical energy to an external load and a liquid disposed in the casing. The liquid may be a dielectric liquid which is thermally coupled with the one or more heat generating electronic components, the circuit board and the casing. The liquid has a thermal conductivity and a thermal capacitance such that the liquid provides cooling for the one or more heat generating components and heat distribution by way of the casing such that a temperature of the outer surface of the casing is equalised.

The liquid provides a liquid cooling system which provides cooling for the one or more heat generating components by thermal transfer from the heat generating component to the liquid and heat distribution by movement of the liquid away from the heat generating component. The movement of the liquid may occur by natural or forced convection. The liquid also provides thermal equalisation of the power supply since the liquid distributes heat over the entire volume of the casing due to the convection of the liquid within the casing and heat transfer from the liquid to the casing. Thus the formation of hot spots in the casing is avoided.

The casing may have a liquid-tight seal. The dielectric liquid may be in direct contact with the one or more heat generating electronic components, the circuit board and the casing. In embodiments in which the casing has a liquid-tight seal, the dielectric liquid may be in direct contact with an inner surface of the casing.

In some embodiments, at least one further member is arranged between the casing and one or more of the heat generating electronic components. The at least one further member is thermally coupled with the one or more heat generating components and the casing. The at least one further member may enclose the dielectric liquid and may have a liquid-tight seal. The at least one further member may be in direct contact with the casing or a further member, such as a dielectric liquid, may be arranged between the inner surface of the casing and an outer surface of the further member.

The input port and the output port may have various forms which may be different from one another. For example, the input port may include a socket, a lead or a plug and the output port may include a socket, a lead or a plug.

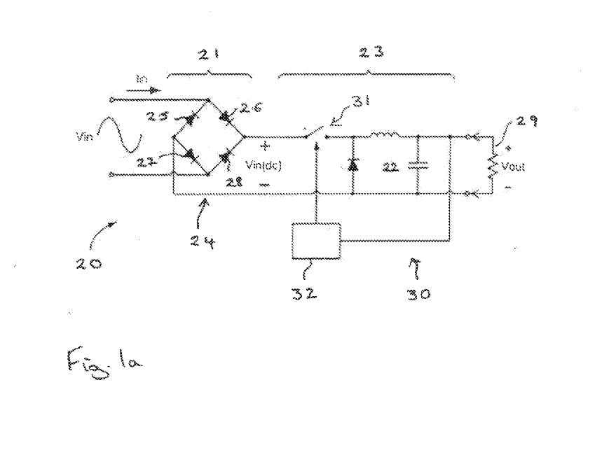

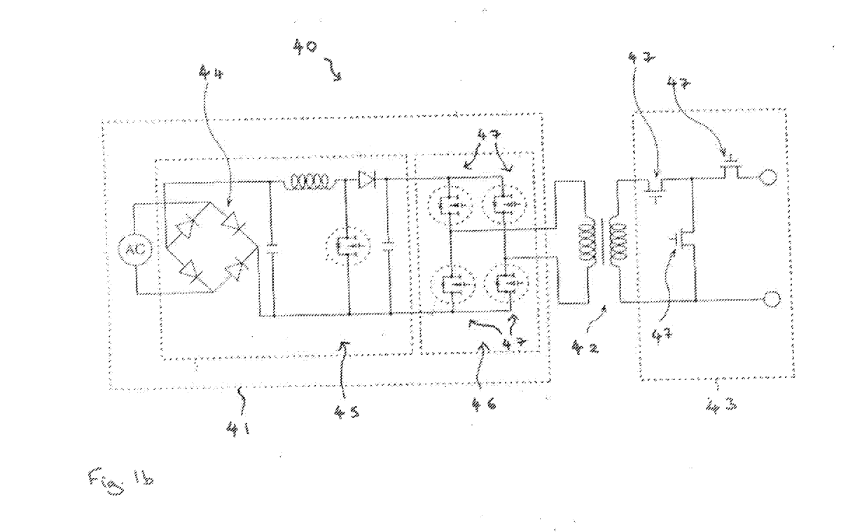

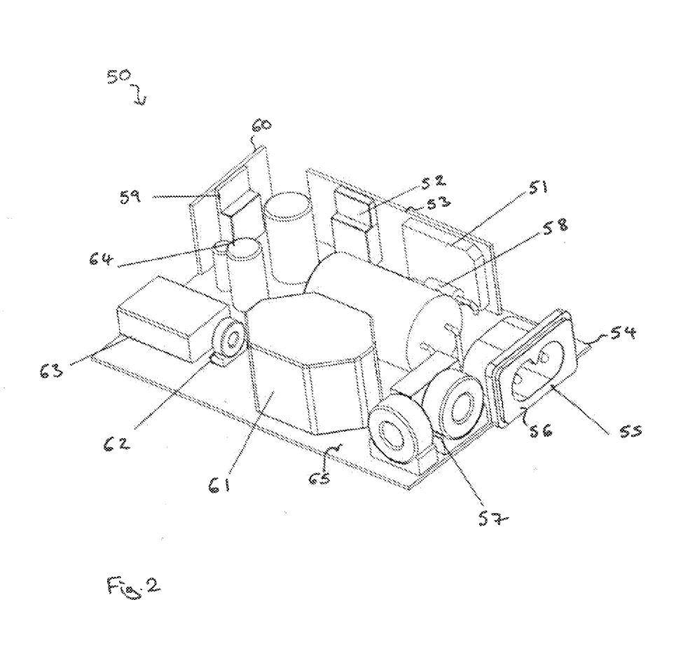

The liquid cooling system may be used for power supplies having different power conversion circuits and for power supplies having different topologies. FIGS 1a and 1b illustrate examples of power conversion circuits and FIGS. 2 to 4 illustrate examples of power supply topologies with which the liquid cooling system according to one of the embodiments described herein may be used.

FIG. 1a illustrates a circuit diagram of a power supply for converting alternating current to direct current. The power supply includes a power conversion circuit 20 which includes a primary side circuit 21, an inductor 22 and a secondary side circuit 23. The primary side circuit 21 receives alternating current, for example provided by an AC mains supply, by way of an input port. The AC to DC rectification is, in this embodiment, accomplished using a bridge rectifier 24 including four diodes 25, 26, 27, 28. The bridge rectifier 24 converts the positive and negative half cycles of the AC input voltage Vᵢₙ to a full wave rectified waveform of constant polarity. To produce the desired steady DC output voltage Vₒᵤₜ across a load 29 coupled to the output of the power conversion circuit 20, the rectified waveform is filtered by a smoothing circuit coupled to the output of the bridge rectifier 24.

The smoothing circuit functions to maintain the DC output voltage near the peak voltage during the low portions of the AC input voltage Vᵢₙ. Some amount of AC ripple is superimposed on the DC output Vₒᵤₜ depending on the smoothing circuit used. The smoothing circuit may be a smoothing capacitor coupled to the output of the bridge rectifier, for example. Additional filtering may also be employed to reduce the ripple to an acceptable level. The DC output voltage Vₒᵤₜ produced by the primary side has a peak voltage Vₚₑₐₖ near to that of the AC input voltage V. However, many applications may require much lower voltage. For example, many devices require a DC voltage of 12 V DC, or even less, whereas the AC voltage Vᵢₙ may be 230 V for residential AC mains in some countries.

To lower the DC voltage to the required level, a stepdown transformer or DC-DC converter 30 may be used in the secondary side circuit. A DC-DC converter 30 may include a switch 31, such as a transistor, a diode, an inductor, a filter capacitor and a pulse width modulator (PWM) control 32. The PWM control 32 controls the opening and closing of the switch 31 at a fixed frequency that is much higher than the 50 Hz frequency of the AC mains, which may be 50 Hz or 60 Hz. Typically the PWM control controls the opening and enclosing of the switch at a frequency of greater than 1 kHz.

When the switch 31 is turned on, current flows through the switch 31, the inductor 22, into the filter capacitor and the load 29. The increasing current causes the magnetic field of the inductor to build up energy to be stored in the inductor's magnetic field. When the switch is turned off, the voltage drop across the inductor quickly reverses polarity and the energy stored by the inductor is used as a current source for the load. The DC output voltage Vₒᵤₜ is determined by the proportion of time the switch is on (Tₒₙ) in a period T, where T is 1/f. More specifically, Vout is equal to DVᵢₙ(DC), where D=Tₒₙ/T is known as the duty cycle and Vᵢₙ(DC) is the source DC input voltage provided at the output of the bridge rectifier 24. The PWM controller 32 is configured in a feedback path, allowing it to regulate the DC output voltage Vₒᵤₜ by modulating the duty cycle D. In some embodiments, the power supply may include several outputs, each providing a different DC voltage, or differing DC voltages may be provided at a single output.

Heat is generated by various components used in the primary side circuit 21 and, typically to a lesser extent, by components of the secondary side circuit 23. The liquid cooling system according to one or more of the embodiments described herein may be used to provide cooling of the components.

FIG. 1b illustrates a circuit diagram of a further power conversion circuit 40 for converting alternating current to direct current. The power conversion circuit 40 includes a primary side circuit 41, a transformer 42 and a secondary side circuit 43. The primary side circuit 41 receives alternating current, for example from an AC mains supply. The primary side circuit 41 includes a bridge rectifier 44, a power correction factor circuit 45 and a full bridge 46 including four transistors 47. The transistors may be silicon-based MOSFET devices or gallium nitride-based High Electron Mobility Transistors (HEMT), for example. The secondary side circuit 43 includes three further transistors 47. However, the power supplies described in the following description are not limited to having one of the power conversion circuits illustrated in FIG. 1a or FIG. 1b. These circuit diagrams are merely examples of circuits which may be provided using one or more features of one or more of the power supplies described below.

FIG. 2 illustrates a three-dimensional perspective view of components of a power conversion circuit of a power supply 50. In operation, the components are housed in a non-illustrated casing. The power supply 50 includes a bridge rectifier 51 and primary side transistor 52 which may be mounted on a heatsink 53 positioned substantially in perpendicular to a major surface of a circuit board 54. The input port 55 is arranged on the major surface of the circuit board 54 and, in this embodiment, includes a socket 56 with two pins. However other types of input port 55 may be used, for example, a cable which is hard wired to the circuit board 54. The power supply 50 includes chokes 57 as an input filter and a capacitor 58. The secondary side includes a transistor 59 which is also mounted on a heatsink 60 arranged substantially perpendicular to the major surface of the circuit board 54. A transformer 61 is mounted on the circuit board 54 along with an output inductor 62 and output port 63 which, in this embodiment may be USB type output port. However, the output port 63 is not limited to this configuration and may include other forms, such as a socket for receiving a single pin. Output capacitors 64 are also arranged on the circuit board 54. The various components may be arranged on a single side 65 of the circuit board 54. Power is received at the input port 55 and converted by the power conversion circuit provided by the various components of the power supply 50, for example from alternating current to direct current, and the converted power, i.e. the direct current, may be supplied to an external load by way of the output port 63.

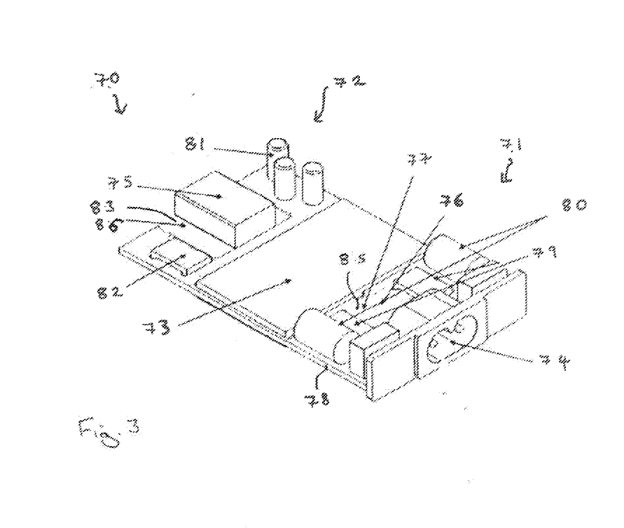

A three-dimensional perspective view of a further example of a power supply 70 is illustrated in FIG. 3 and a top view of the power supply 70 is illustrated in FIG. 4. The illustrated components are housed within a non-illustrated casing during operation. The power supply 70 includes a primary side circuit 71, a secondary side circuit 72 and a transformer 73. The transformer 73 is arranged between the primary side circuit 71 and the secondary side circuit 72. The power supply 70 further includes an input port 74, which in the illustrated embodiment, is configured to as a socket to accept a connector from, for example, a cable and an output port 75 including a socket, for example the USB socket.

The primary side circuit 71 includes a bridge rectifier circuit 76 and at least one transistor 77. The bridge rectifier 76 and the transistor 77 are arranged proximal to the input port 74 and embedded in a first embedding region 85 in the circuit board 78 of the power supply 70. The first embedding region 85 is arranged underneath the input port 74. The further components of the primary side circuit 71, such as planar choke input filters 79 and capacitors 80 are also arranged between the transformer 73 and the input port 74. The further components may be arranged adjacent the first embedding region 85 and may be embedded in the circuit board 78 or may be mounted on the upper surface of the circuit board 78. The transformer 73 has a planar configuration and is also mounted in a cavity of the circuit board 78 arranged between the primary side circuit 71 and the secondary side circuit 72.

In the secondary side circuit 72, at least one secondary side transistor 83 is embedded in a second embedding region 86 within the circuit board 78 and is positioned proximal the output port 75. The second embedding region 86 is positioned underneath the output port 75 in this embodiment. In this embodiment, the secondary side transistor 83 is arranged at least partially underneath the output port 75. Output capacitors 81 and a planar inductor 82 are arranged adjacent the output port 75 and the second embedding region 86. The components of the secondary side circuit 72 are arranged between the transformer 73 and the output port 75. By embedding the bridge rectifier 76, primary side transistor 77, secondary side transistor 83 and transformer 73 within the circuit board 78 of the power supply 70, the overall dimensions and, in particular, the height of the power supply 70 may be reduced over an arrangement in which each of these electronic components is provided in a separate package and/or combined into one or more submodules which are mounted on the upper surface of the circuit board 78.

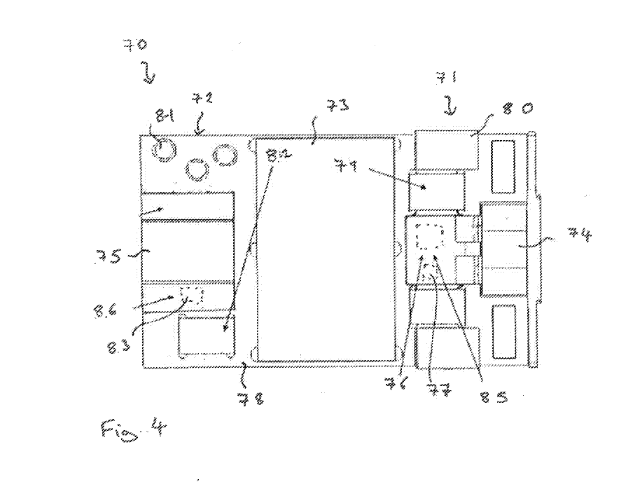

The secondary side circuit 72 may provide a DC-DC converter for converting the voltage output from the bridge rectifier 76 to a different DC voltage. Typically, the voltage output from the bridge rectifier 76 is higher than that required for the device or device is attached to the output port 75. For example, the voltage output by the bridge rectifier 76 may be 230 V which corresponds to the voltage of residential AC mains supply received at the input port 74. The device to be attached to the output port 75 may, however, require a lower voltage of 12 V or less, for example 3 V. The power supply illustrated in FIGS. 4 and 5 has an input port 74 and output port 75 which are adapted to detachably receive a further connector. However, the power supply 70 may include an input port 74 which is hardwired to a power supply and/or the output port 75 may be hardwired to a device receiving the converted power.

The power supply may also have more than one output port. For example, the power supply may include two or more output ports which may have different forms. This may enable two or more devices to be supplied with power at the same time and/or enable devices with different input ports to be supplied with power from the power supply. Heat may be dissipated from heat generating components within the power supply 70, such as the bridge rectifier 76, the primary side transistor 77 and, to a lesser extent, the secondary side transistor 83 and planar transformer 73.

FIGS. 5 to 8 illustrate embodiments of liquid cooling systems for use with a power supply having a power conversion circuit such as those illustrated in FIGS. 1 to 4. The liquid is contained within a liquid-tight casing and is in thermal contact and direct contact with heat generating components of the power conversion circuit and with the casing. Natural or forced convection of the liquid within the casing provides liquid circulation paths within the casing which are used to distribute heat around the volume so as to avoid the formation of hot spots at the outer surface of the casing. Convection of the liquid leads to a temperature equalization of the casing and of the components within the casing.

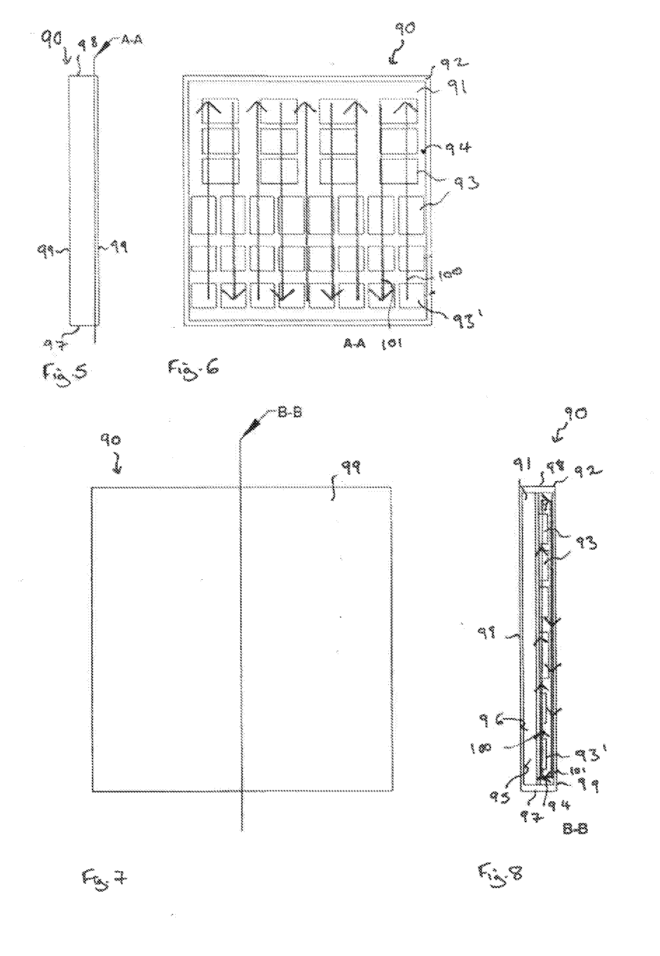

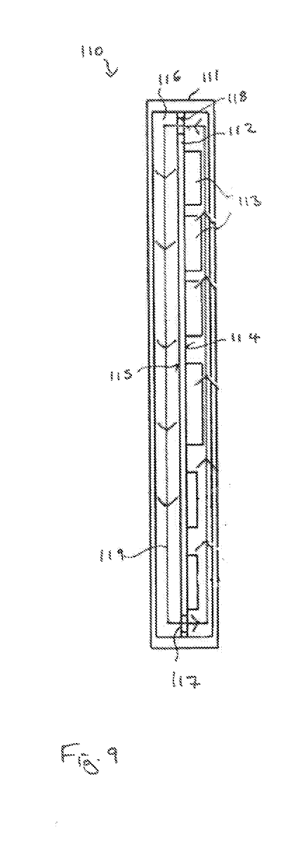

FIG. 5 illustrates a schematic side view of a power supply 90 having a liquid cooling system, FIG. 6 a schematic view of the power supply 90 along the line A-A, FIG. 7 a schematic view of a major surface of the power supply 90, and FIG. 8 a cross-sectional view along the line B-B. A circuit board 91 is arranged within a casing 92 of the power supply 90. A plurality of electronic components 93 is arranged on a single side 94 of the circuit board 91. The size, shape and configuration of the plurality of electronic components 93 illustrated are a purely schematic depiction which is used for purposes of illustrating heat dissipation by the liquid cooling system. The number of electronic components 93 and the size, shape, configuration of the electronic components 93 is not limited to that as illustrated and may vary.

The rear surface 95 of the circuit board 91 is spaced at a distance from the inner surface 96 of the casing 92. A liquid for liquid cooling is disposed in the casing 92 which has a liquid tight seal. Both sides 94, 95 of the circuit board 91 and the electronic components 93 may be immersed in the liquid. The liquid may be a dielectric such that the electronic components 93 and the circuit board 91 immersed in the liquid are electrically insulated from one another. The casing 92 may not be completely filled with the liquid in order to provide an expansion volume.

In operation, the power supply 90 is arranged such that a first minor side face 97 of the casing 92 is arranged towards the bottom and an opposing second minor side face 98 is arranged towards top, whereby the major surfaces 99 of the casing 92 and the circuit board 91 are substantially vertical. During operation of the power supply 90, one or more of the electronic components generates heat. For the purpose of illustration, the electronic component 93′ is depicted as generating heat which is thermally transferred to the liquid in the vicinity of the electronic component 93′ such that the temperature of the liquid in this region increased. This encourages convection of the warmer liquid portion such that the hot liquid rises, as indicated by the arrow 100, from the bottom to the top with the casing 92. The liquid cools by thermal conduction to the casing 92, cooler portions of the liquid, the circuit board 91 and the electronic components 93 and by heat dissipation via the casing 92 into the environment. The cooled liquid then flows towards the bottom of the casing 92, as indicated by the arrow 101, creating a liquid circulation path. Such a mechanism may be considered as natural convection of the liquid. Natural convection occurs due to the thermal gradient produced by the asymmetric arrangement of the heat generating electronic components 93′ on a single side 94 of the circuit board 91.

The natural convection of the liquid provides cooling for the heat generating electronic component 93′ as heat is removed from and distributed away from the electronic component 93′. Thermal equalization and hot spots are avoided since the heat can be dissipated via the liquid throughout the volume of the casing 92 and over the entire surface area of the casing 92, rather than the heat being transferred to only a localised area of the casing 92 by, for example, a heat sink arranged between the electronic component 93′ and the casing 92.

The liquid may be a dielectric in order to avoid short circuits between the electronic components 93 and the casing 92. The liquid may have a thermal conductivity of at least 0.5 W/m·K and/or a thermal capacitance of at least 0.3 kJ/kg·K. These values of the thermal conductivity and thermal capacitance are greater than those of air. Liquids with these properties may be used to provide improved cooling and thermal equalisation. The liquid may include mineral oil, silicon oil, natural ester-based oil, synthetic ester-based oil or a perfluorinated fluid.

In arrangements in which the fluid paths are constrained or interrupted or in which frictional losses are higher than the forces driving the convection, natural convection will be reduced or may be prevented. In some embodiments, natural convection of the liquid within the casing is assisted by suitable selection of the liquid viscosity and the provision of baffles or other liquid constrictors based in and around the electronic components on the circuit board.

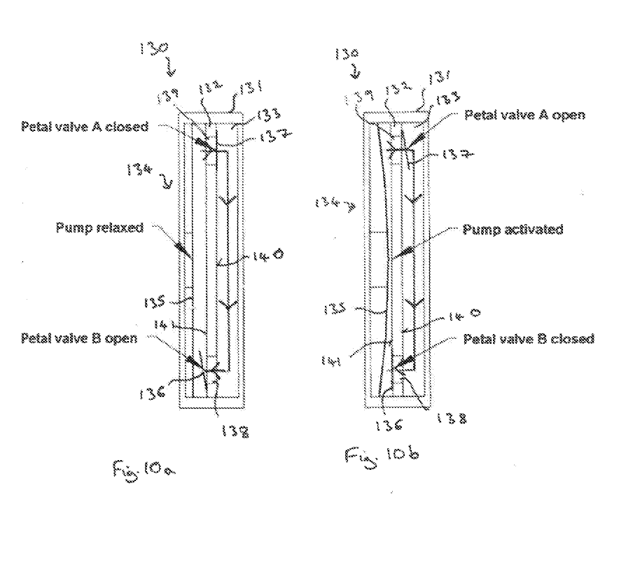

FIG. 9 illustrates a cross-sectional view of a power supply 110 including a casing 111 enclosing a circuit board 112 on which a plurality of electronic components 113 are mounted. The electronic components 113 are arranged on a single major surface 114 of the circuit board 112 and provide a power conversion circuit. The opposing major surface 115 of the circuit board 112 is spaced at a distance from the inner surface of the casing 111 and may include no electronic components or electronic components which generate little or substantially no heat.

A liquid cooling system is provided for the power supply 110 which includes a dielectric liquid 116 enclosed in the casing 111. The electronic components 113 may be immersed in the dielectric liquid 116. The liquid cooling system includes two or more apertures or bores 117, 118 in the circuit board 112 which are used for assisting natural convection of the dielectric liquid 116 within the casing 111. The apertures 117, 118 are arranged in the circuit board 112 such that the dielectric liquid 116 acting as a coolant and heat dissipator for thermal equalisation may flow through the apertures 117, 118 from one side of the circuit board 112 to the other.

In operation, the circuit board 112 is substantially vertical. At least one aperture 117 is arranged towards the bottom and at least one aperture 118 is arranged towards the top of the circuit board 112. The heat generating electronic components 113 are arranged on a single major surface of the circuit board 112 which leads to an asymmetry of heat generation and of thermal loading of the circuit. This asymmetry of the heat generation encourages the formation of circulation paths in the liquid from the heat generating side 114 of the circuit board 112 to the opposing side 115 of the circuit board 112 as is indicated schematically in FIG. 9 by the arrows 119. In this particular example, an anticlockwise liquid circulation path is created. The liquid cooling system provides thermal equalization to avoid the formation of hot spots since the heat can be dissipated via the dielectric liquid 116 throughout the volume of the casing 111 and over the entire surface area of the casing 111.

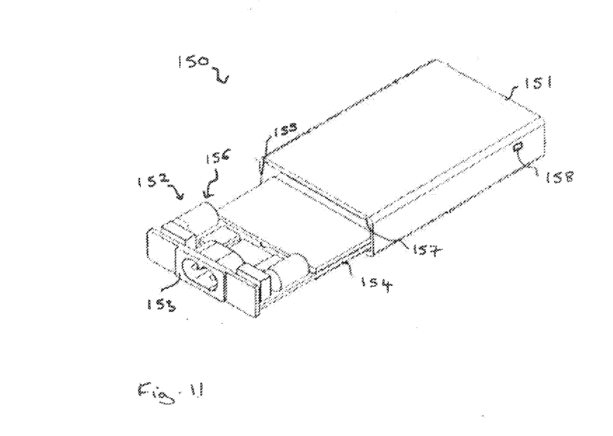

FIGS. 10a and 10b illustrate a power supply 130 including a casing 131 enclosing a circuit board 132 and a dielectric liquid 133. The circuit board 132 is arranged within the casing 131 such that it is surrounded on both sides by the liquid 133. A plurality of electronic components providing a power conversion circuit is arranged on the circuit board 132. The power conversion circuit and the electronic components are not illustrated in FIG. 10 in order to ease the illustration of the liquid circulation paths providing cooling and thermal equalization for the power supply 130.

The power supply 130 includes a fluid circulator 134. The fluid circulator 134 may be used to provide forced convection of the liquid 133 within the casing 131 and heat generating components of the power conversion circuit of the power supply 130. In this embodiment, the fluid circulator 134 has the form of a piezoelectric-based membrane pump 135 and petal or reed valves 136, 137. The petal valves 136, 137 are sized, shaped and arranged to close and open respective apertures 138, 139 arranged in the circuit board 132. In particular, at least one aperture 138 is arranged towards the bottom of power supply 130 and a second aperture 139 is arranged towards the top of the power supply 130. The heat generating components of the power conversion circuit are arranged on a first major surface 140 of the circuit board 132 such that the thermal loading within the casing is asymmetric.

In a first operation state illustrated in FIG. 10a, the pump 135 is relaxed, the petal valve 136 is open allowing liquid to flow through the aperture 138 from regions adjacent the first major surface 140 to regions adjacent the opposing second major surface 141 and the petal valve 137 is closed preventing liquid from flowing through the aperture 139. The circulation path is indicated by arrow 142. In the second operation state illustrated in FIG. 10b, in which the pump 135 is activated, the petal valve 136 is closed and the petal valve 137 is open allowing liquid to flow from the adjacent the second surface 141 of the circuit board 132 to the regions adjacent opposing first surface 140 of the circuit board 132. The liquid circulation path is indicated with arrow 143. The fluid circulator 134 is configured such that the natural convection path of the liquid within the casing 131 is encouraged.

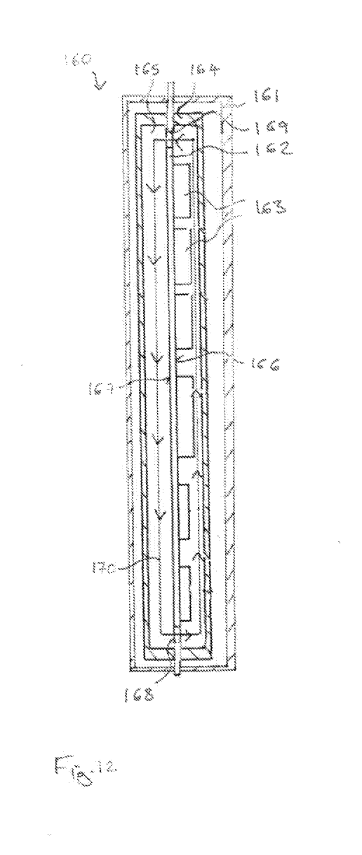

FIG. 11 illustrates a schematic perspective view of a power supply 150 with a casing 151 and a partially inserted power supply module 152 including an input port 153, a circuit board 154 and a plurality of components 156 providing a power conversion circuit. A seal 155 is provided between a wall 157 defining the casing 151 and the module 152 such that casing 151 is liquid-tight when closed. A port 158 in the casing 151 may be provided for filling the casing 151 with the liquid of the liquid cooling system. In the embodiment illustrated in FIG. 11, the power supply module 152 provides an AC-DC converter including a planar transformer and rectifying and switching components embedded within the circuit board 154. However, the casing 151 may be used for power supplies in which the rectifying and switching components and the transformer not mounted within the circuit board, but are mounted on one side of the circuit board.

In the embodiments illustrated in FIGS. 5 to 11, the casing is sealed in a liquid-tight manner such that the dielectric liquid may be in direct contact with the inner surface of the casing. However, in some embodiments, one or more further members may be arranged between the casing and the dielectric liquid. The member may form an enclosure around one or more of the heat generating electronic components. The member may provide a liquid-tight seal such that the dielectric liquid is not in direct contact with the casing. However, the dielectric liquid is thermally coupled with the casing via the member so that the dielectric liquid is able to provide cooling for the one or more heat generating electronic components and to provide heat distribution by way of the casing such that the temperature of the outer surface of the casing is equalised. If the member has a liquid-tight seal, a liquid-tight seal for the casing may be omitted.

FIG. 12 illustrates a cross-sectional view of a power supply 160 including a casing 161 enclosing a circuit board 162 on which a plurality of electronic components 163 are mounted. An additional member forming an enclosure 164 is arranged between the casing 161 and the electronic components 163. The additional enclosure 164 surrounds the circuit board 162 and has a liquid-tight seal. The dielectric cooling liquid 165 is disposed in and contained within the enclosure 164. The enclosure 164 may be flexible.

The electronic components 163 are arranged such that the heat generation is asymmetric within the enclosure 164. In this embodiment, the electronic components 163 are arranged on a single major surface 166 of the circuit board 162 and provide a power conversion circuit. The opposing major surface 167 of the circuit board 162 is spaced at a distance from the inner surface of the enclosure 164 and may include no electronic components or electronic components which generate little or substantially no heat. The electronic components 163 may be immersed in the dielectric liquid 165.

The liquid cooling system provided for the power supply 160 includes the dielectric liquid 165 contained within the enclosure 164 and two or more apertures or bores 168, 169 in the circuit board 162 which are used for assisting convection of the dielectric liquid 165 within the enclosure 164. The convection of the dielectric liquid 165 may be natural or forced. The apertures 168, 169 are arranged in the circuit board 162 such that the dielectric liquid 165 acting as a coolant and heat dissipator for thermal equalisation may flow through the apertures 168, 169 from one side of the circuit board 162 to the other.

In operation, the circuit board 162 is substantially vertical such that at least one aperture 168 is arranged in a lower plane than at least one aperture 169 which is arranged in a higher plane above the at least one aperture 168. The heat generating electronic components 163 are arranged on a single major surface 166 of the circuit board 162 which leads to an asymmetry of heat generation and of thermal loading of the circuit. This asymmetry of the heat generation encourages the formation of circulation paths in the liquid from the heat generating side 164 of the circuit board 162 to the opposing side 165 of the circuit board 162 as is indicated schematically in FIG. 12 by the arrows 170. In this particular example, an anticlockwise liquid circulation path is created.

The liquid cooling system provides thermal equalization to avoid the formation of hot spots since the heat can be dissipated via the dielectric liquid 165 and enclosure 164 throughout the volume of the casing 161 and over the entire surface area of the casing 161 since the dielectric liquid 165 and enclosure 164 are thermally coupled with the casing 161.

The enclosure 164 may be in direct contact with an inner surface of the casing 161 at one or more positions or may be spaced at a distance from an inner surface of the casing 161. In embodiments in which the enclosure 164 is spaced at a distance from the inner surface of the casing 161, a further thermally conductive material may be arranged between the enclosure 164 and the casing 161 to assist in thermally coupling the enclosure 164 to the casing 161. For example, the further thermally conductive material may be a dielectric liquid, a dielectric gel or a solid dielectric.

Spatially relative terms such as “under”, “below”, “lower”, “over”, “upper” and the like are used for ease of description to explain the positioning of one element relative to a second element. These terms are intended to encompass different orientations of the device in addition to different orientations than those depicted in the figures.

Further, terms such as “first”, “second”, and the like, are also used to describe various elements, regions, sections, etc. and are also not intended to be limiting. Like terms refer to like elements throughout the description. As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power supply, comprising:
a casing enclosing a circuit for power conversion comprising one or more heat generating electronic components mounted on a circuit board;
an input port configured to receive electrical energy from a power source;
an output port configured to supply electrical energy to an external load; and
a dielectric liquid disposed in the casing and being thermally coupled with the one or more heat generating electronic components, the circuit board and the casing, the dielectric liquid having a thermal conductivity and a thermal capacitance such that the dielectric liquid provides cooling for the one or more heat generating electronic components and heat distribution by way of the casing such that a temperature of the outer surface of the casing is equalised.

2. The power supply of claim 1, wherein the dielectric liquid has a thermal conductivity of at least 0.5 W/m·K.

3. The power supply of claim 1, wherein the dielectric liquid has a thermal capacitance of at least 0.3 kJ/kg·K

4. The power supply of claim 1, wherein the dielectric liquid is selected from the group consisting of mineral oil, silicon oil, natural ester-based oil, synthetic ester-based oil and a perfluorinated fluid.

5. The power supply of claim 1, wherein the one or more heat generating electronic components is immersed in the dielectric liquid.

6. The power supply of claim 1, wherein the circuit board comprises at least two apertures sized, shaped and arranged to assist liquid circulation by natural convection.

7. The power supply of claim 1, further comprising one or more baffles for directing flow of the dielectric liquid by natural convection.

8. The power supply of claim 1, further comprising a fluid circulator located in the housing for circulating the dielectric liquid by forced convection

9. The power supply of claim 8, wherein the fluid circulator is selected from the group consisting of an electromechanical actuator and a piezoelectric pump.

10. The power supply of claim 8, wherein the circuit board comprises at least two apertures, sized, shaped and arranged to assist liquid circulation by forced convection.

11. The power supply of claim 1, further comprising an expansion volume.

12. The power supply of claim 1, wherein the casing is sealed in a liquid-tight manner and the dielectric liquid is in direct contact with an inner surface of the casing.

13. The power supply of claim 1, further comprising at least one member arranged between one or more of the heat generating electronic components and the casing, the at least one member being thermally coupled with the one or more heat generating components and the casing.

14. The power supply of claim 13, wherein the at least one member encloses the dielectric liquid.

15. The power supply of claim 1, wherein the one or more heat generating electronic components comprises at least one or more of a rectifier and a switching transistor.

16. The power supply of claim 15, wherein the rectifier comprises a plurality of switches configured in a bridge circuit.

17. The power supply of claim 1, wherein the power conversion circuit comprises circuitry for converting alternating current to direct current.

18. A method, comprising:
receiving, at an input port of a power supply, electrical energy from a power source;
supplying the received electrical energy to one or more of a rectifier and a switching transistor; and
dissipating at least a portion of thermal energy generated by one or more of the rectifier and the switching transistor from the power supply by way of convection of a dielectric liquid that is thermally coupled with the one or more of the rectifier and the switching transistor and a casing of the power supply such that a temperature at an outer surface of the casing is equalised.

19. The method of claim 18, further comprising assisting convection of the liquid by a fluid circulator.

20. A power supply, comprising:
means for enclosing a dielectric liquid in a liquid-tight manner;
means for receiving, at an input port of a power supply, electrical energy from a power source;
means for converting the received electrical energy by one or more of a rectifier and a switching transistor;
means for transmitting the converted electrical energy to an external load; and
means for dissipating at least a portion of thermal energy generated by one or more of the rectifier and the switching transistor by way of the dielectric liquid and the means for enclosing the liquid such that a temperature at an outer surface of means for enclosing the dielectric liquid is equalised.
